(19) United States
(12) Patent Application Publication
(10) Pub. No.: US 2012/0206877 A1
(43) Pub. Date: Aug. 16, 2012

(54) CAPACITOR MODULE

(75) Inventors: Sang Woong Park, Gyeonggi-do (KR); Do Hyun Kim, Seoul (KR); Chan Yoon, Seoul (KR); Bae Kyun Kim, Gyeonggi-do (KR)

(73) Assignees: ZALMAN TECH CO., LTD., Seoul (KR); SAMSUNG ELECTRO-MECHANICS., LTD, Suwon (KR)

(21) Appl. No.: 13/372,799

(22) Filed: Feb. 14, 2012

(30) Foreign Application Priority Data
Feb. 15, 2011 (KR) 10-2011-0013293

(51) Int. Cl. H05K 7/20

(52) U.S. Cl. 361/689; 361/688

(57) ABSTRACT

Disclosed herein is a capacitor module including at least one capacitor, a cooling case accommodating the capacitor, and a cooling unit disposed in the cooling case and cooling a side surface of the capacitor.

According to the present invention, cooling efficiency of the capacitor is maximized and fixing force of the capacitor in the cooling case is superior so that product reliability of the capacitor module can be improved.

### CROSS REFERENCE(S) TO RELATED APPLICATIONS

This application claims the benefit under 35 U.S.C. Section 119 of Korean Patent Application Serial No. 10-2011-0013293, entitled “Capacitor Module” filed on Feb. 15, 2011, which is hereby incorporated by reference in its entirety into this application.

### BACKGROUND OF THE INVENTION

1. Technical Field

The present invention relates to a capacitor module, and more particularly, to a capacitor module capable of maximizing cooling efficiency of a capacitor and having improved fixing force of the capacitor in a cooling case.

2. Description of the Related Art

The car industry has advanced rapidly over the past 100 years, which mainly focused on gasoline and diesel internal combustion engines, but today, is facing great changes such as environmental regulations and energy security threat along with the depletion of fossil fuel.

All the countries in the world including advanced countries are competing desperately to develop environmentally-friendly cars, and all car makers are striving to survive the competition for technical development of an environmentally-friendly car for the future, which requires environmentally-friendly and high technology of high efficiency.

In particular, in order to meet the demands of the times for developing more environmentally-friendly products, while solving the depletion problem of fossil fuel, the car makers are actively conducting a study on an electric car, which uses an electric motor as a driving source, in recent years.

A field that is most actively studied currently is about a hybrid vehicle and a fuel cell vehicle.

The hybrid vehicle refers to combining two or more different driving sources effectively and driving a vehicle in a broad sense, but in most cases, refers to a vehicle that obtains a driving force from an engine using fuel such as gasoline or diesel and an electric motor (driving motor). This vehicle may be called a hybrid electric vehicle (HEV).

Such a hybrid type vehicle mounts an engine and a generator-motor therein as a driving source, and has a capacitor device storing electricity generated by the generator-motor driven by the engine.

The capacitor device serves to function as a power source to supply electricity to the generator-motor. As a capacitor device, a capacitor module 1 having a high capacity capacitor is applied, as shown in FIGS. 1 and 2.

However, since driving and deceleration of the hybrid type vehicle are frequently repeated, load applied to the capacitor 11 of the related-art capacitor module 1 greatly fluctuates and an amount of heat emitted from the capacitor easily increases. Thus, there is a problem in that the capacitor rapidly deteriorates and a lifespan of the capacitor is reduced.

In order to prevent this problem, a cooling means is provided in the capacitor module, for cooling the capacitor and dissipating the heat generated from the capacitor 11 effectively.

The related art capacitor module 1 forms a channel 13 with a cooling medium flowing therein on a bottom surface 12a of a heat dissipating body 12 in which the capacitor 11 is accommodated, in order to cool a lower end surface of the capacitor.

However, since the heat is mainly emitted from a body of the capacitor 11, that is, a side surface, rather than the bottom surface of the capacitor 11, the cooling method of the related art capacitor module has difficulty in increasing cooling efficiency of the capacitor.

Also, the capacitor 11 of the related art capacitor module 1 is seated on a metal plate 14 fixed to an inner bottom surface of the heat dissipating body 12 and is accommodated in the heat dissipating body 12. However, since the metal plate 14 only divides the capacitor 11 and has no structure to fix the capacitor, there is a problem in that the related art capacitor module is vulnerable to vibration or shock.

### SUMMARY OF THE INVENTION

An object of the present invention is to provide a capacitor module capable of maximizing cooling efficiency of a capacitor.

Another object of the present invention is to provide a capacitor module capable of improving fixing force of a capacitor.

According to an exemplary embodiment of the present invention, there is provided a capacitor module including: at least one capacitor, a cooling case accommodating the capacitor, and a cooling unit disposed in the cooling case and cooling a side surface of the capacitor.

The cooling unit may include: a cooling channel allowing coolant to flow therein, and contacting the side surface of the capacitor to cool the side surface of the capacitor through the flow of the coolant, a coolant supply unit supplying the coolant to the cooling channel, and a coolant discharge unit discharging the coolant cooling the side surface of the capacitor from the cooling channel.

The cooling channel may include: an upper cooling channel disposed on an upper portion of the side surface of the capacitor, and supplied with the coolant from the coolant supply unit to cool the upper portion of the side surface of the capacitor, and a lower cooling channel disposed on a lower portion of the side surface of the capacitor to fluidly communicate with the upper cooling channel, and supplied with the coolant from the upper cooling channel to cool the lower portion of the side surface of the capacitor and then to discharge the coolant to the coolant discharge unit.

The capacitor module may further include a heat transfer member disposed between the side surface of the capacitor and the cooling channel.

The heat transfer member may include a thermal pad made of a silicon material.

The capacitor module may further include a seating member disposed on an inner bottom surface of the cooling case and allowing a lower end portion of the capacitor to be seated thereon when the capacitor is accommodated in the cooling case.

The seating member may include a pad made of a rubber material.

The seating member may have a lower end support portion protruding therefrom, the lower end support portion fixedly supporting a side surface of the lower end portion of the capacitor.

The capacitor module may further include a bracket disposed above the cooling case and covering an upper end portion of the capacitor when the capacitor is accommodated in the cooling case.

The bracket may have an upper end support portion protruding therefrom, the upper end support portion fixedly supporting a side surface of the upper end portion of the capacitor.

### BRIEF DESCRIPTION OF THE DRAWINGS

FIG. 1 is an exploded perspective view schematically illustrating a related art capacitor module;

FIG. 2 is a bottom perspective view schematically illustrating the heat dissipating body, the gasket, and the cover of FIG. 1;

FIG. 3 is an exploded perspective view schematically illustrating a capacitor module according to an exemplary embodiment of the present invention;

FIG. 4 is a perspective view schematically illustrating the cooling case and the cooling unit of FIG. 3;

FIG. 5 is a configuration view explaining the flow of coolant in the cooling channel of FIG. 4;

FIG. 6 is a perspective view schematically illustrating the seating member of FIG. 3; and

FIGS. 7A and 7B are a top perspective view and a bottom perspective view schematically illustrating the bracket of FIG. 3.

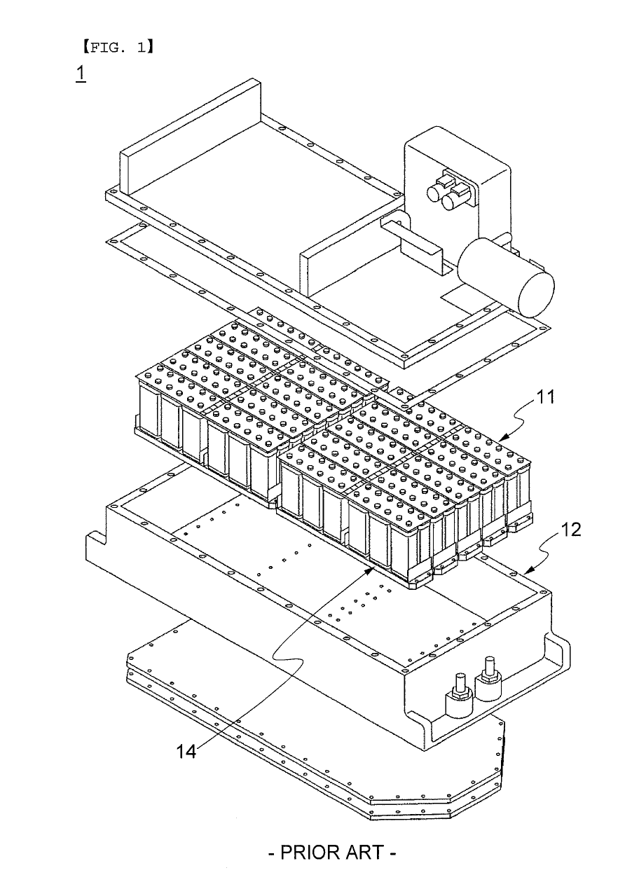

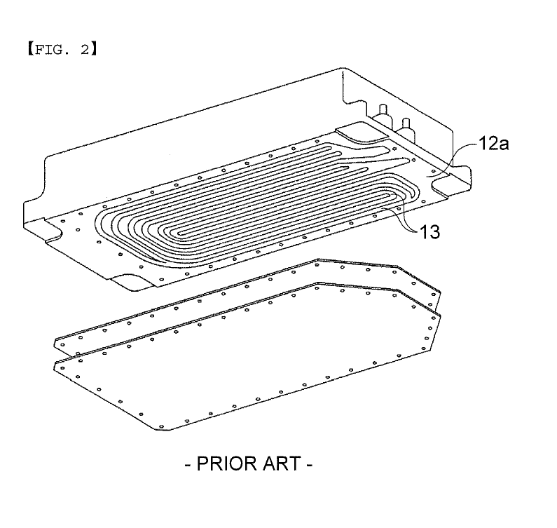

### DESCRIPTION OF THE PREFERRED EMBODIMENTS

Exemplary embodiments of the present invention in which objects of the present invention may be specifically implemented will be described with reference to the accompanying drawings. In exemplary embodiments of the present invention, the same terms and reference numerals will be used to describe the same components. Therefore, an additional description for the same component will be omitted below.

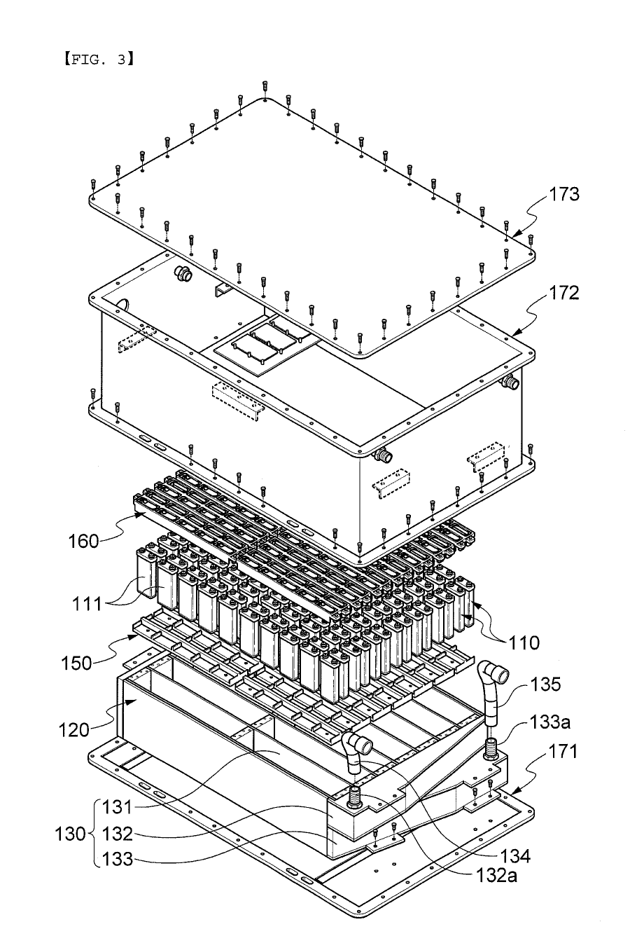

Hereinafter, a capacitor module according to an exemplary embodiment of the present invention will be explained with reference to FIGS. 3 to 6.

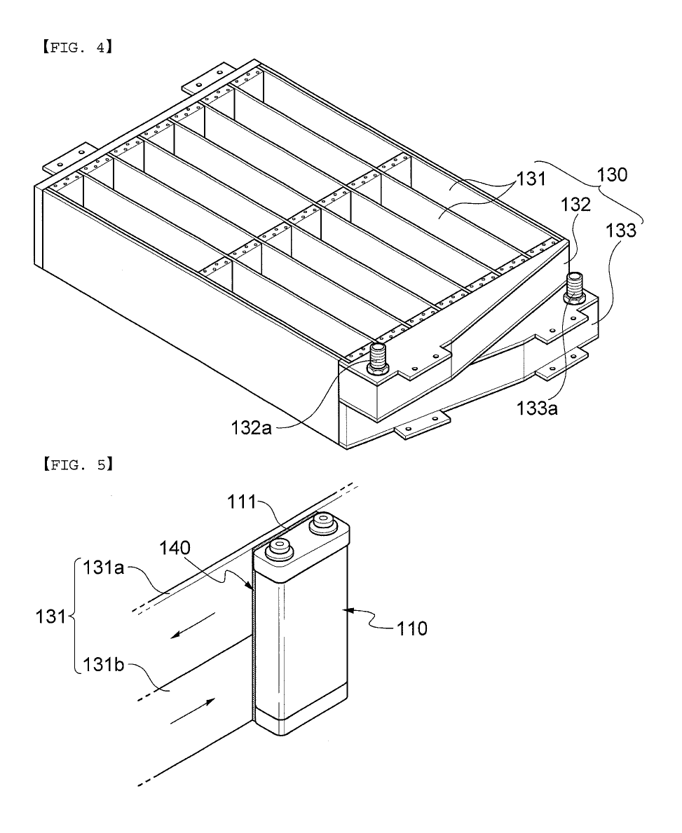

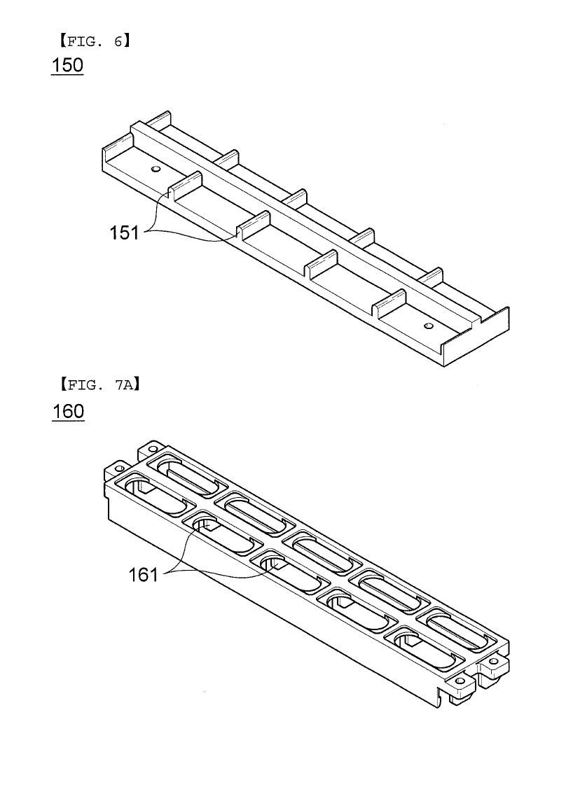

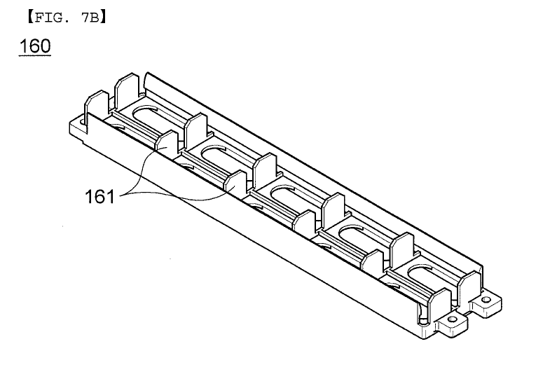

FIG. 3 is an exploded perspective view schematically illustrating a capacitor module according to an exemplary embodiment of the present invention, FIG. 4 is a perspective view schematically illustrating the cooling case and the cooling unit of FIG. 3, FIG. 5 is a configuration view explaining the flow of coolant in the cooling channel of FIG. 4, FIG. 6 is a perspective view schematically illustrating the seating member of FIG. 3, and FIGS. 7A and 7B are a top perspective view and a bottom perspective view schematically illustrating the bracket of FIG. 3.

Referring to FIG. 3, a capacitor module 100 according to an exemplary embodiment of the present invention includes a plurality of capacitors 110, a cooling case 120 accommodating the capacitors 110, and a cooling unit 130 disposed in the cooling case 120 to cool side surfaces 111 of the capacitors 110.

As shown in FIG. 4, the cooling unit 130 may include a cooling channel 131 in which coolant flows and which contacts the side surfaces 111 of the plurality of capacitors 110 to cool the side surfaces 111 of the plurality of capacitors 110 through the flow of the coolant, a coolant supply unit 132 supplying the coolant to the cooling channel 131, and a coolant discharge unit 133 discharging the coolant cooling the side surfaces 111 of the plurality of capacitors 110 from the cooling channel 131.

The cooling channel 131 is disposed among the plurality of capacitors 110 to divide the plurality of capacitors 110 from one another in the cooling case 120, and cools the side surface 111 of each capacitor 110.

In this case, the cooling channel 131 is configured to contact the side surface with a wider size among the side surfaces of each capacitor 110, and thus further improves cooling efficiency of the capacitors 110.

Also, as shown in FIG. 5, in order to further improve the cooling efficiency on the side surface 111 of the capacitor 110, the cooling channel 131 may include an upper cooling channel 131a and a lower cooling channel 131b corresponding to an upper portion and a lower portion of the side surface 111 of the capacitor 110, respectively, and allowing the coolant to flow in opposite directions with reference to the side surface 111 of the capacitor 110.

More specifically, the upper cooling channel 131a is located on the upper portion of the side surface 111 of the capacitor 110 to be supplied with the coolant from the coolant supply unit 132 and cool the upper portion of the side surface 111 of the capacitor 110.

Also, the lower cooling channel 131b is located on the lower portion of the side surface 111 of the capacitor 110 to fluidly communicate with the upper cooling channel 131a, and is supplied with the coolant from the upper cooling channel 131a and cools the lower portion of the side surface 1111 of the capacitor 110, and then discharges the coolant to the coolant discharge unit 133.

The capacitor module 100 according to the exemplary embodiment may further include a heat transfer member 140 disposed between the side surface 111 of the capacitor 110 and the cooling channel 131.

The heat transfer member 140 may include a thermal pad made of a silicon material. The thermal pad may contact the cooling channel 131 in close contact with the side surface 111 of the capacitor 110 when the capacitor 110 is accommodated in the cooling case 120.

Accordingly, the heat transfer member 140 improves a heat transfer effect between the capacitor 110 and the cooling channel 131 and thus further improves the cooling efficiency of the capacitor 110.

The coolant supply unit 132 has a coolant inlet 132a through which the coolant flows in and a coolant supply pipe 134 is connected to the coolant inlet 132a.

Accordingly, the coolant may be supplied to the coolant supply unit 132 having the coolant inlet 132a through the coolant supply pipe 134 from a pump (not shown).

The coolant discharge unit 133 includes a coolant outlet 133a discharging the coolant and a coolant discharge pipe 135 is connected to the coolant outlet 133a.

Accordingly, the coolant cooling the side surface 111 of the capacitor 110 may be discharged outside through the coolant discharge pipe 135.

The coolant supply unit 132 may be formed to have a volume gradually decreasing from the coolant inlet 132a to an opposite side along a side surface of the cooling case 120 in order to minimize pressure loss while supplying the coolant. That is, the coolant supply unit 132 may be formed to have a larger volume at the coolant inlet 132 so that the coolant is uniformly supplied to the upper cooling channel 131a.

The coolant discharge unit 133 may be disposed under the coolant supply unit 132 in an inverse form of the coolant supply unit 132 in order to minimize pressure loss while discharging the coolant.

As shown in FIGS. 3 and 6, the capacitor module 100 according to the exemplary embodiment may further include a seating member 150 disposed on an inner bottom surface of the cooling case 120 to allow lower end portions of the capacitors 110 to be seated thereon when the capacitors 110 are accommodated in the cooling case 120.

In this case, the seating member 150 may include a pad made of a rubber material, and may have a lower end support portion 151 protruding from a seating surface thereof, the lower end support portion 151 fixedly supporting a side surface of the lower end portion of the capacitor 110.

Accordingly, the lower end portions of the capacitors 110 are fixedly supported through the seating member 150 so that durability of the capacitor 110 can be improved in response to external vibration and shock due to improved fixing force, when the capacitors 110 are accommodated in the cooling case 120.

As shown in FIG. 3 and FIGS. 7A and 7B, the capacitor module 100 according to the exemplary embodiment may further include a bracket 160 disposed above the cooling case 120 to cover upper end portions of the capacitors 110 when the capacitors 110 are accommodated in the cooling case 120.

The bracket 160 may have an upper end support portion 161 protruding therefrom, the upper end support portion 161 fixedly supporting a side surface of the upper end portion of the capacitor 110.

Accordingly, the upper end portions of the capacitors 110 are fixedly supported through the bracket 160 so that the durability of the capacitor 110 can be further improved in response to external vibration and shock due to improved fixing force when the capacitors 110 are accommodated in the cooling case 120.

The capacitor module 100 according to the exemplary embodiment may include an exterior case protecting the inner parts and forming an exterior, and the exterior case includes a lower case 171 in which the cooling case 120 is seated and fixed, a main body case 172 assembled with the lower case 171 to enclose the cooling case 120, and an upper case 173 assembled with the main body case 172 to cover the upper end of the cooling case 120.

As described above, the capacitor module according to the present invention cools the side surface of the capacitor, which is the main heat emitting portion of the capacitor, so that the cooling efficiency of the capacitor can be maximized.

Also, the capacitor module according to the present invention securely fixes the capacitor in the cooling case by means of the seating member and the bracket, so that the fixing force of the capacitor can be improved and the capacitor module is invulnerable to vibration and shock.

Although the preferred embodiments of the present invention have been disclosed for illustrative purposes, those skilled in the art will appreciate that various modifications, additions, and substitutions are possible, without departing from the scope and spirit of the invention as disclosed in the accompanying claims. Accordingly, such modifications, additions and substitutions should also be understood to fall within the scope of the present invention.

What is claimed is:

1. A capacitor module comprising:
at least one capacitor;
a cooling case accommodating the capacitor; and
a cooling unit disposed in the cooling case and cooling a side surface of the capacitor.

2. The capacitor module according to claim 1, wherein the cooling unit includes:
a cooling channel allowing coolant to flow therein, and contacting the side surface of the capacitor to cool the side surface of the capacitor through the flow of the coolant;
a coolant supply unit supplying the coolant to the cooling channel; and
a coolant discharge unit discharging the coolant cooling the side surface of the capacitor from the cooling channel.

3. The capacitor module according to claim 2, wherein the cooling channel includes:
an upper cooling channel disposed on an upper portion of the side surface of the capacitor, and supplied with the coolant from the coolant supply unit to cool the upper portion of the side surface of the capacitor; and
a lower cooling channel disposed on a lower portion of the side surface of the capacitor to fluidly communicate with the upper cooling channel, and supplied with the coolant from the upper cooling channel to cool the lower portion of the side surface of the capacitor and then to discharge the coolant to the coolant discharge unit.

4. The capacitor module according to claim 2, further comprising a heat transfer member disposed between the side surface of the capacitor and the cooling channel.

5. The capacitor module according to claim 4, wherein the heat transfer member includes a thermal pad made of a silicon material.

6. The capacitor module according to claim 1, further comprising a seating member disposed on an inner bottom surface of the cooling case and allowing a lower end portion of the capacitor to be seated thereon when the capacitor is accommodated in the cooling case.

7. The capacitor module according to claim 6, wherein the seating member includes a pad made of a rubber material.

8. The capacitor module according to claim 6, wherein the seating member has a lower end support portion protruding therefrom, the lower end support portion fixedly supporting a side surface of the lower end portion of the capacitor.

9. The capacitor module according to claim 1, further comprising a bracket disposed above the cooling case and covering an upper end portion of the capacitor when the capacitor is accommodated in the cooling case.

10. The capacitor module according to claim 9, wherein the bracket has an upper end support portion protruding therefrom, the upper end support portion fixedly supporting a side surface of the upper end portion of the capacitor.
